(19) United States
(12) Patent Application Publication
(10) Pub. No.: US 2013/0155630 A1
(43) Pub. Date: Jun. 20, 2013

(54) Touch Sensor with Passive Electrical Components

(71) Applicants: Esat Yilmaz, Santa Cruz, CA (US); David Brent Guard, Southampton (GB)

(72) Inventors: Esat Yilmaz, Santa Cruz, CA (US); David Brent Guard, Southampton (GB)

(21) Appl. No.: 13/331,893

(22) Filed: Dec. 20, 2011

(51) Int. Cl. H05K 7/02; H05K 3/30

(52) U.S. Cl. 361/748; 29/832

(57) ABSTRACT

In one embodiment, an apparatus includes a substrate, a touch sensor, and a passive electrical component. The touch sensor is disposed on the substrate. The passive electrical component is disposed on a surface of the substrate. The passive electrical component is formed at least in part of conductive material.

### TECHNICAL FIELD

This disclosure generally relates to touch sensors.

### BACKGROUND

A touch sensor may detect the presence and location of a touch or the proximity of an object (such as a user's finger or a stylus) within a touch-sensitive area of the touch sensor overlaid on a display screen, for example. In a touch sensitive display application, the touch sensor may enable a user to interact directly with what is displayed on the screen, rather than indirectly with a mouse or touch pad. A touch sensor may be attached to or provided as part of a desktop computer, laptop computer, tablet computer, personal digital assistant (PDA), smartphone, satellite navigation device, portable media player, portable game console, kiosk computer, point-of-sale device, or other suitable device. A control panel on a household or other appliance may include a touch sensor.

There are a number of different types of touch sensors, such as (for example) resistive touch screens, surface acoustic wave touch screens, and capacitive touch screens. Herein, reference to a touch sensor may encompass a touch screen, and vice versa, where appropriate. When an object touches or comes within proximity of the surface of the capacitive touch screen, a change in capacitance may occur within the touch screen at the location of the touch or proximity. A touch sensor controller may process the change in capacitance to determine its position on the touch screen.

### BRIEF DESCRIPTION OF THE DRAWINGS

FIG. 1 illustrates an example touch sensor with an example controller.

FIG. 2 illustrates an example substrate bonded to an example flexible printed circuit (FPC).

FIG. 3 illustrates an example resistor made of fine lines of metal or other conductive material that is formed on the substrate of FIG. 2.

FIG. 4A illustrates in cross section an example capacitor made of fine lines of metal or other conductive material that is formed on the substrate of FIG. 2.

FIG. 4B illustrates in a three-dimensional view the example capacitor of FIG. 4A.

FIG. 5A illustrates an example inductor made of fine lines of metal or other conductive material that is formed on the substrate of FIG. 2.

FIG. 5B illustrates another example inductor made of fine lines of metal or other conductive material that is formed on the substrate of FIG. 2.

FIG. 5C illustrates another example inductor made of fine lines of metal or other conductive material that is formed on the substrate of FIG. 2.

FIG. 5D illustrates another example inductor made of fine lines of metal or other conductive material that is formed on the substrate of FIG. 2.

FIG. 6A is a schematic diagram of an example LC filter made of fine lines of metal or other conductive material formed on the substrate of FIG. 2.

FIG. 6B illustrates another example LC filter made of fine lines of metal or other conductive material formed on the substrate of FIG. 2.

FIG. 7A is a schematic diagram of an example RC filter made of fine lines of metal or other conductive material formed on the substrate of FIG. 2.

FIG. 7B illustrates another example RC filter made of fine lines of metal or other conductive material formed on the substrate of FIG. 2.

### DESCRIPTION OF EXAMPLE EMBODIMENTS

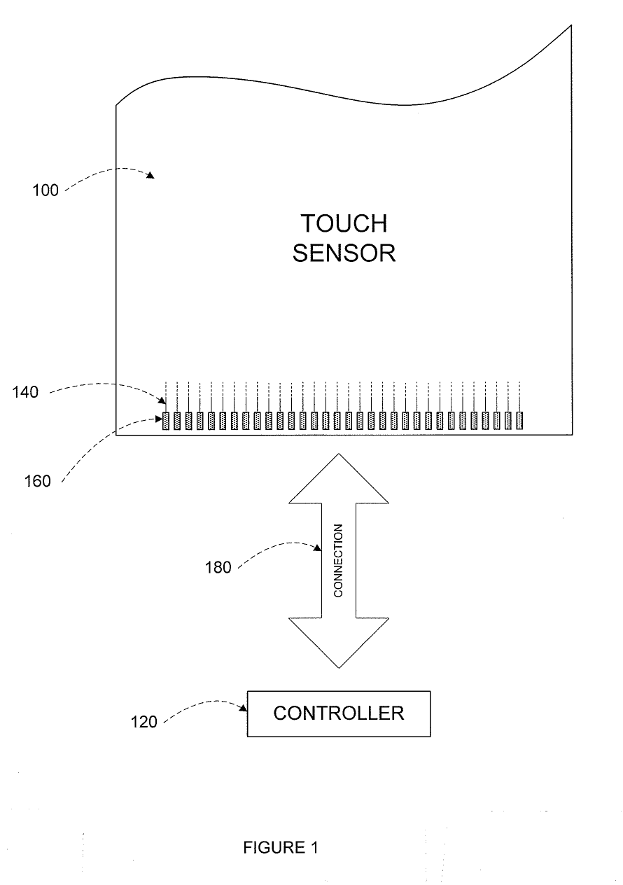

FIG. 1 illustrates an example touch sensor 100 with an example touch-sensor controller 120. Touch sensor 100 and touch-sensor controller 120 may detect the presence and location of a touch or the proximity of an object within a touch-sensitive area of touch sensor 100. Herein, reference to a touch sensor may encompass both the touch sensor and its touch-sensor controller, where appropriate. Similarly, reference to a touch-sensor controller may encompass both the touch-sensor controller and its touch sensor, where appropriate. Touch sensor 100 may include one or more touch-sensitive areas, where appropriate. Touch sensor 100 may include an array of drive and sense electrodes (or an array of electrodes of a single type) disposed on one or more substrates, which may be made of a dielectric material. Herein, reference to a touch sensor may encompass both the electrodes of the touch sensor and the substrate(s) that they are disposed on, where appropriate. Alternatively, where appropriate, reference to a touch sensor may encompass the electrodes of the touch sensor, but not the substrate(s) that they are disposed on.

An electrode (whether a drive electrode or a sense electrode) may be an area of conductive material forming a shape, such as for example a disc, square, rectangle, other suitable shape, or suitable combination of these. One or more cuts in one or more layers of conductive material may (at least in part) create the shape of an electrode, and the area of the shape may (at least in part) be bounded by those cuts. In particular embodiments, the conductive material of an electrode may occupy approximately 100% of the area of its shape. As an example and not by way of limitation, an electrode may be made of indium tin oxide (ITO) and the ITO of the electrode may occupy approximately 100% of the area of its shape, where appropriate. In particular embodiments, the conductive material of an electrode may occupy substantially less than 100% (such as for example, approximately 5%) of the area of its shape. As an example and not by way of limitation, an electrode may be made of fine lines of metal (FLM) or other conductive material (such as for example copper, silver, or a copper- or silver-based material) and the fine lines of conductive material may occupy substantially less than 100% (such as for example, approximately 5%) of the area of its shape in a hatched, mesh, or other suitable pattern. Although this disclosure describes or illustrates particular electrodes made of particular conductive material forming particular shapes with particular fills having particular patterns, this disclosure contemplates any suitable electrodes made of any suitable conductive material forming any suitable shapes with any suitable fills having any suitable patterns. Where appropriate, the shapes of the electrodes (or other elements) of a touch sensor may constitute in whole or in part one or more macro-features of the touch sensor. One or more macro-features of a touch sensor may determine one or more characteristics of its functionality. One or more characteristics of the implementation of those shapes (such as, for example, the conductive materials, fills, or patterns within the shapes) may constitute in whole or in part one or more micro-features of the touch sensor. One or more micro-features of the touch sensor may determine one or more optical features of the touch sensor, such as transmittance, refraction, or reflection.

A mechanical stack may contain the substrate (or multiple substrates) and the conductive material forming the drive or sense electrodes of touch sensor 100. As an example and not by way of limitation, the mechanical stack may include a first layer of optically clear adhesive (OCA) beneath a cover panel. The cover panel may be clear and made of a resilient material suitable for repeated touching, such as for example glass, polycarbonate, or poly(methyl methacrylate) (PMMA). This disclosure contemplates any suitable cover panel made of any suitable material. The first layer of OCA may be disposed between the cover panel and the substrate with the conductive material forming the drive or sense electrodes. The mechanical stack may also include a second layer of OCA and a dielectric layer (which may be made of PET or another suitable material, similar to the substrate with the conductive material forming the drive or sense electrodes). As an alternative, where appropriate, a thin coating of a dielectric material may be applied instead of the second layer of OCA and the dielectric layer. The second layer of OCA may be disposed between the substrate with the conductive material making up the drive or sense electrodes and the dielectric layer, and the dielectric layer may be disposed between the second layer of OCA and an air gap to a display of a device including touch sensor 100 and touch-sensor controller 120. As an example only and not by way of limitation, the cover panel may have a thickness of approximately 1 mm; the first layer of OCA may have a thickness of approximately 0.05 mm; the substrate with the conductive material forming the drive or sense electrodes may have a thickness of approximately 0.05 mm; the second layer of OCA may have a thickness of approximately 0.05 mm; and the dielectric layer may have a thickness of approximately 0.05 mm. Although this disclosure describes a particular mechanical stack with a particular number of particular layers made of particular materials and having particular thicknesses, this disclosure contemplates any suitable mechanical stack with any suitable number of any suitable layers made of any suitable materials and having any suitable thicknesses. As an example and not by way of limitation, in particular embodiments, a layer of adhesive or dielectric may replace the dielectric layer, second layer of OCA, and air gap described above, with there being no air gap to the display.

One or more portions of the substrate of touch sensor 100 may be made of polyethylene terephthalate (PET) or another suitable material. This disclosure contemplates any suitable substrate with any suitable portions made of any suitable material. In particular embodiments, the drive or sense electrodes in touch sensor 100 may be made of ITO in whole or in part. In particular embodiments, the drive or sense electrodes in touch sensor 100 may be made of fine lines of metal or other conductive material. As an example and not by way of limitation, one or more portions of the conductive material may be copper or copper-based and have a thickness of approximately 5 μm or less and a width of approximately 10 μm or less. As another example, one or more portions of the conductive material may be silver or silver-based and similarly have a thickness of approximately 5 μm or less and a width of approximately 10 μm or less. This disclosure contemplates any suitable electrodes made of any suitable material.

Touch sensor 100 may implement a capacitive form of touch sensing. In a mutual-capacitance implementation, touch sensor 100 may include an array of drive and sense electrodes forming an array of capacitive nodes. A drive electrode and a sense electrode may form a capacitive node. The drive and sense electrodes forming the capacitive node may come near each other, but not make electrical contact with each other. Instead, the drive and sense electrodes may be capacitively coupled to each other across a space between them. A pulsed or alternating voltage applied to the drive electrode (by touch-sensor controller 120) may induce a charge on the sense electrode, and the amount of charge induced may be susceptible to external influence (such as a touch or the proximity of an object). When an object touches or comes within proximity of the capacitive node, a change in capacitance may occur at the capacitive node and touch-sensor controller 120 may measure the change in capacitance. By measuring changes in capacitance throughout the array, touch-sensor controller 120 may determine the position of the touch or proximity within the touch-sensitive area(s) of touch sensor 100.

In a self-capacitance implementation, touch sensor 100 may include an array of electrodes of a single type that may each form a capacitive node. When an object touches or comes within proximity of the capacitive node, a change in self-capacitance may occur at the capacitive node and touch-sensor controller 120 may measure the change in capacitance, for example, as a change in the amount of charge needed to raise the voltage at the capacitive node by a pre-determined amount. As with a mutual-capacitance implementation, by measuring changes in capacitance throughout the array, touch-sensor controller 120 may determine the position of the touch or proximity within the touch-sensitive area(s) of touch sensor 100. This disclosure contemplates any suitable form of capacitive touch sensing, where appropriate.

In particular embodiments, one or more drive electrodes may together form a drive line running horizontally or vertically or in any suitable orientation. Similarly, one or more sense electrodes may together form a sense line running horizontally or vertically or in any suitable orientation. In particular embodiments, drive lines may run substantially perpendicular to sense lines. Herein, reference to a drive line may encompass one or more drive electrodes making up the drive line, and vice versa, where appropriate. Similarly, reference to a sense line may encompass one or more sense electrodes making up the sense line, and vice versa, where appropriate.

Touch sensor 100 may have drive and sense electrodes disposed in a pattern on one side of a single substrate. In such a configuration, a pair of drive and sense electrodes capacitively coupled to each other across a space between them may form a capacitive node. For a self-capacitance implementation, electrodes of only a single type may be disposed in a pattern on a single substrate. In addition or as an alternative to having drive and sense electrodes disposed in a pattern on one side of a single substrate, touch sensor 100 may have drive electrodes disposed in a pattern on one side of a substrate and sense electrodes disposed in a pattern on another side of the substrate. Moreover, touch sensor 100 may have drive electrodes disposed in a pattern on one side of one substrate and sense electrodes disposed in a pattern on one side of another substrate. In such configurations, an intersection of a drive electrode and a sense electrode may form a capacitive node. Such an intersection may be a location where the drive electrode and the sense electrode “cross” or come nearest each other in their respective planes. The drive and sense electrodes do not make electrical contact with each other—instead they are capacitively coupled to each other across a dielectric at the intersection. Although this disclosure describes particular configurations of particular electrodes forming particular nodes, this disclosure contemplates any suitable configuration of any suitable electrodes forming any suitable nodes. Moreover, this disclosure contemplates any suitable electrodes disposed on any suitable number of any suitable substrates in any suitable patterns.

As described above, a change in capacitance at a capacitive node of touch sensor 100 may indicate a touch or proximity input at the position of the capacitive node. Touch sensor controller 120 may detect and process the change in capacitance to determine the presence and location of the touch or proximity input. Touch-sensor controller 120 may then communicate information about the touch or proximity input to one or more other components (such one or more central processing units (CPUs) or digital signal processors (DSPs)) of a device that includes touch sensor 100 and touch-sensor controller 120, which may respond to the touch or proximity input by initiating a function of the device (or an application running on the device) associated with it. Although this disclosure describes a particular touch-sensor controller having particular functionality with respect to a particular device and a particular touch sensor, this disclosure contemplates any suitable touch-sensor controller having any suitable functionality with respect to any suitable device and any suitable touch sensor.

Touch-sensor controller 120 may be one or more integrated circuits (ICs)—such as for example general-purpose microprocessors, microcontrollers, programmable logic devices or arrays, application-specific ICs (ASICs). In particular embodiments, touch-sensor controller 120 comprises analog circuitry, digital logic, and digital non-volatile memory. In particular embodiments, touch-sensor controller 120 is disposed on an FPC bonded to the substrate of touch sensor 100, as described below. In particular embodiments, multiple touch-sensor controllers 120 are disposed on the FPC. In some embodiments, the FPC may have no touch-sensor controllers 120 disposed on it. The FPC may couple touch sensor 10 to a touch-sensor controller 12 located elsewhere, such as for example, on a printed circuit board of the device. Touch-sensor controller 120 may include a processor unit, a drive unit, a sense unit, and a storage unit. The drive unit may supply drive signals to the drive electrodes of touch sensor 100. The sense unit may sense charge at the capacitive nodes of touch sensor 100 and provide measurement signals to the processor unit representing capacitances at the capacitive nodes. The processor unit may control the supply of drive signals to the drive electrodes by the drive unit and process measurement signals from the sense unit to detect and process the presence and location of a touch or proximity input within the touch-sensitive area(s) of touch sensor 100. The processor unit may also track changes in the position of a touch or proximity input within the touch-sensitive area(s) of touch sensor 100. The storage unit may store programming for execution by the processor unit, including programming for controlling the drive unit to supply drive signals to the drive electrodes, programming for processing measurement signals from the sense unit, and other suitable programming, where appropriate. Although this disclosure describes a particular touch-sensor controller having a particular implementation with particular components, this disclosure contemplates any suitable touch-sensor controller having any suitable implementation with any suitable components.

Tracks 14 of conductive material disposed on the substrate of touch sensor 100 may couple the drive or sense electrodes of touch sensor 100 to connection pads 160, also disposed on the substrate of touch sensor 100. As described below, connection pads 160 facilitate coupling of tracks 14 to touch-sensor controller 120. Tracks 14 may extend into or around (e.g. at the edges of) the touch-sensitive area(s) of touch sensor 100. Particular tracks 14 may provide drive connections for coupling touch-sensor controller 120 to drive electrodes of touch sensor 100, through which the drive unit of touch-sensor controller 120 may supply drive signals to the drive electrodes. Other tracks 14 may provide sense connections for coupling touch-sensor controller 120 to sense electrodes of touch sensor 100, through which the sense unit of touch-sensor controller 120 may sense charge at the capacitive nodes of touch sensor 100. Tracks 14 may be made of fine lines of metal or other conductive material. As an example and not by way of limitation, the conductive material of tracks 14 may be copper or copper-based and have a width of approximately 100 μm or less. As another example, the conductive material of tracks 14 may be silver or silver-based and have a width of approximately 100 μm or less. In particular embodiments, tracks 14 may be made of ITO in whole or in part in addition or as an alternative to fine lines of metal or other conductive material. Although this disclosure describes particular tracks made of particular materials with particular widths, this disclosure contemplates any suitable tracks made of any suitable materials with any suitable widths. In addition to tracks 14, touch sensor 100 may include one or more ground lines terminating at a ground connector (which may be a connection pad 160) at an edge of the substrate of touch sensor 100 (similar to tracks 14).

Connection pads 160 may be located along one or more edges of the substrate, outside the touch-sensitive area(s) of touch sensor 100. As described above, touch-sensor controller 120 may be on an FPC. Connection pads 160 may be made of the same material as tracks 14 and may be bonded to the FPC using an anisotropic conductive film (ACF). Connection 180 may include conductive lines on the FPC coupling touch-sensor controller 120 to connection pads 160, in turn coupling touch-sensor controller 120 to tracks 14 and to the drive or sense electrodes of touch sensor 100. This disclosure contemplates any suitable connection 180 between controller 120 and touch sensor 100.

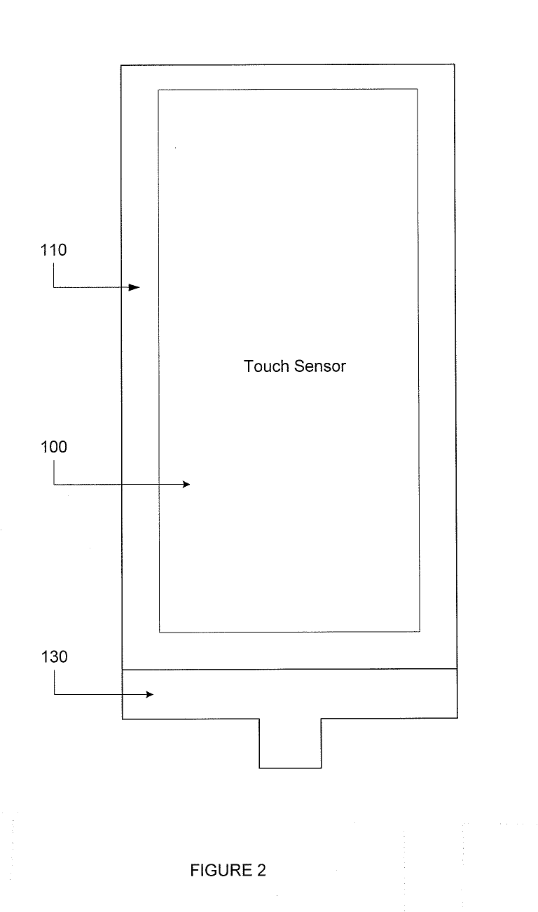

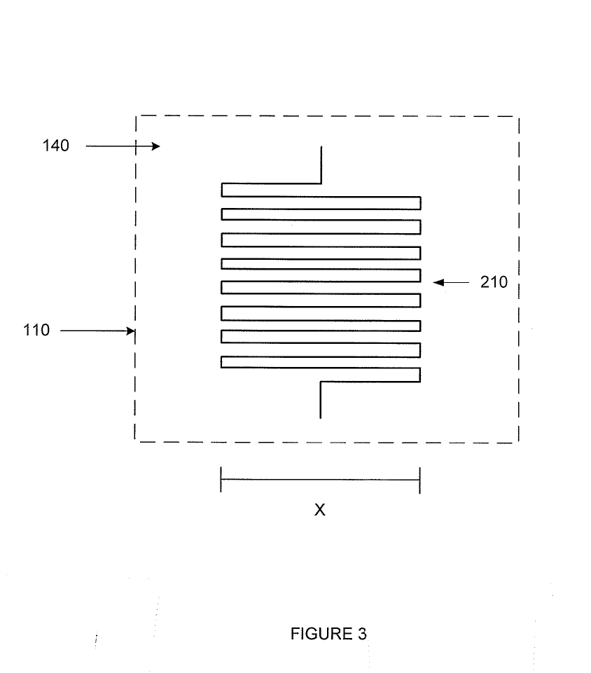

FIG. 2 illustrates an example substrate 110 bonded to an example flexible printed circuit (FPC) 130. FPC 130 is coupled to a controller 120. A touch sensor 100 is disposed on at least a portion of substrate 110. FIGS. 3A through 6B illustrate example electrical components formed on substrate 110. These electrical components (along with electrodes of touch sensor 100) are formed of fine lines of metal or other conductive material, such as for example copper, silver, or a copper- or silver-based material. The material can also be arranged in a flood or a mesh to form particular electrical components. As discussed above with reference to the electrodes of a touch sensor, the fine lines of conductive material occupy substantially less than 100% (such as for example, substantially less than 5%) of the area of its shape in a hatched, mesh, or other suitable pattern. Herein, reference to fine-line metal (FLM) encompasses such material. Electrical components formed on substrate 110 of fine lines of metal or other conductive material are used to form particular circuits, examples of which are discussed below.

FIG. 3 illustrates an example resistor 210 made of fine lines of metal or other conductive material that are formed on the substrate 110 of FIG. 2. In the example of FIG. 3, resistor 210 is formed by an FLM formed in a repeating rectangular pattern. In particular embodiments, resistor 210 couples to substrate 110. Specifically, resistor 210 couples to a surface 140 of substrate 110. Surface 140 is any suitable surface of substrate 110. In this manner, as electrical current flows through the FLM, the electrical current meets a certain resistance as it travels through the repeating rectangular pattern. As an example and not by way of limitation, a resistor 210 may be provided whose dimension X is 1 mm, and the vertical sections 212 are 1 mm each, with a resistance of 1000 Ohms. Various parameters of the resistor can be adjusted.

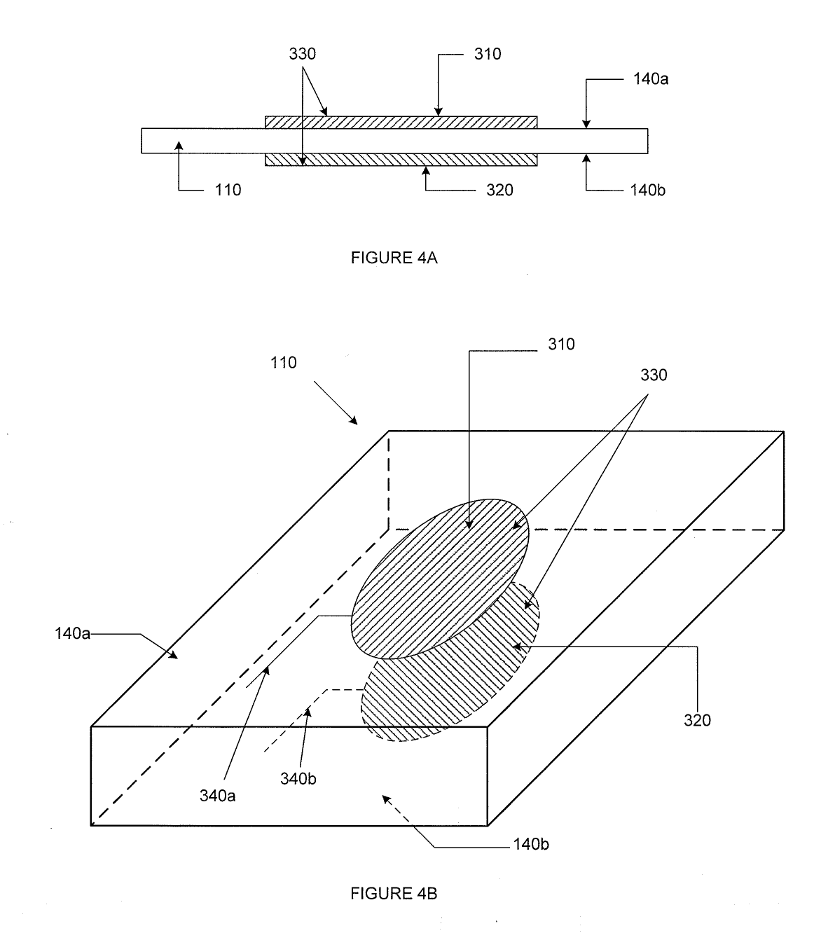

FIGS. 4A and 4B illustrate a capacitor 330 formed on the substrate 110 of FIG. 2. In general, FLM is used to form plates of the capacitor 330. The plates are disposed on opposing surfaces of substrate 110 to form capacitor 330. This process of using FLM to form capacitor 330 on substrate 110 will be discussed further with respect to FIGS. 4A and 4B.

FIG. 4A illustrates in cross section an example capacitor 330 made of fine lines of metal or other conductive material that is formed on the substrate 110 of FIG. 2. As provided by FIG. 4A, substrate 110 includes a first surface 140a and a second surface 140b. Capacitor 330 includes a first plate 310 and a second plate 320. In particular embodiments, first plate 310 and second plate 320 are formed using FLM or other conductive material arranged in a flood or mesh. First plate 310 is disposed on first surface 140a of substrate 210 and second plate 320 is disposed on second surface 140b of substrate 110. A voltage may be applied across wires 340a and 340b to build charge on first plate 310 and/or second plate 320. In this manner, charge builds on first plate 310 and second plate 320 to generate an electric field between first plate 310 and second plate 320. As an example and not by way of limitation, first plate 310 has a surface area of 10 mm², second plate 310 has a surface area of 10 mm², and capacitor 330 has a capacitance of 60 pF. In particular embodiments, substrate 110 acts as a dielectric for capacitor 330. By altering the materials used to form substrate 110, the dielectric constant (ε) of capacitor 330 is varied. As an example and not by way of limitation, substrate 110 has a dielectric constant value of 3.4.

FIG. 4B illustrates in a three-dimensional view the example capacitor 330 of FIG. 4A. As provided by FIG. 4B, capacitor 330 is formed by using FLM or other conductive material arranged in a flood or mesh to form a first plate 310 on first surface 140a and second plate 320 on a second surface 140b. As an example and not by way of limitation, first plate 310 is on a top surface 140a of substrate 110 and second plate 320 is on a bottom surface 140b of substrate 110. First plate 310 and second plate 320 are formed as circles, squares, triangles, or any other suitable shape supported by a surface 140 of substrate 110. In this manner, a capacitive element is formed by placing FLM on surfaces 140 of substrate 110.

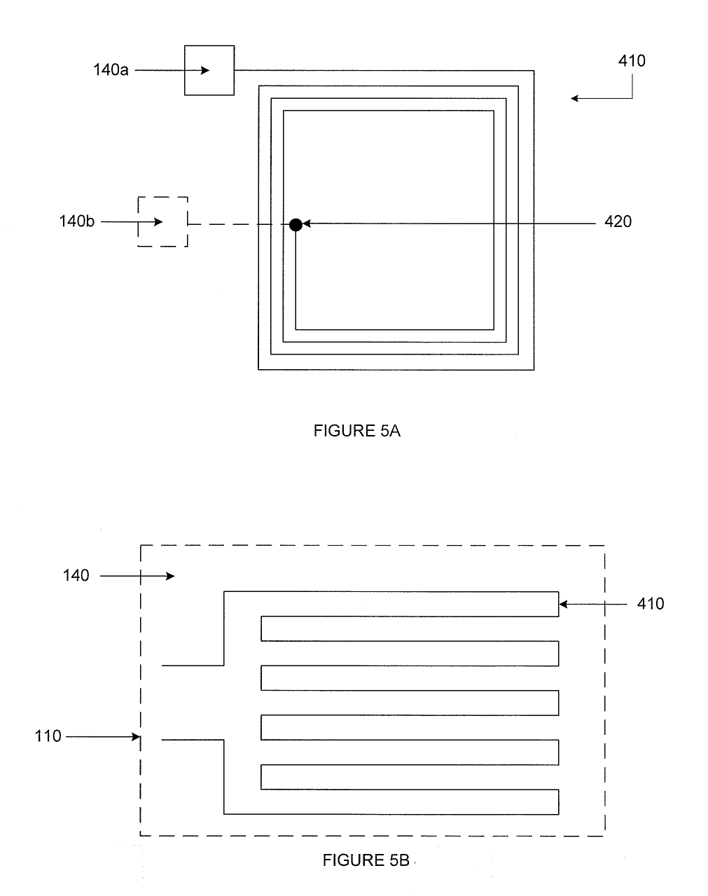

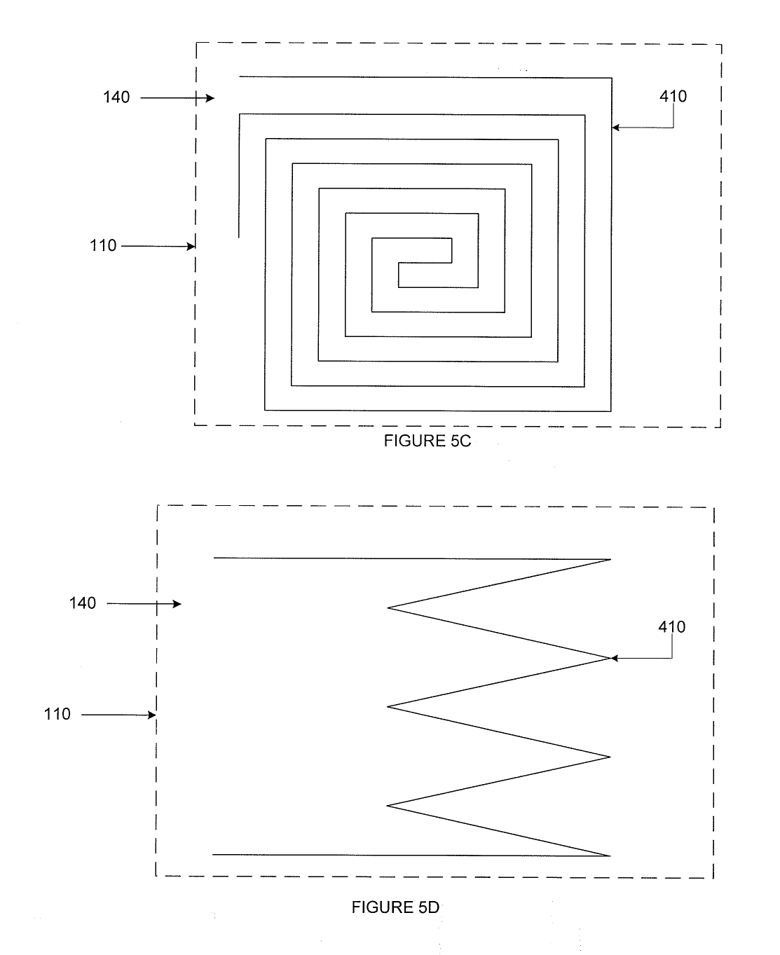

FIG. 5A illustrates an example inductor 410 made of fine lines of metal or other conductive material that is formed on the substrate 110 of FIG. 2. As provided by FIG. 5A, an inductor 410 is formed on substrate 110. In particular embodiments, FLM is used to form a coil. The coil acts as an inductor 410 by resisting changes in electrical current and storing energy in its induced magnetic field. The FLM is formed in an inward spiraling manner to form the coil. In particular embodiments, inductor 410 couples at one end to a first surface 140a and at the other end to a second surface 140b of substrate 110. Inductor 410 is formed on first surface 140a and via 420 is used to couple inductor 410 to second surface 140b. As an example and not by way of limitation, inductor 410 has an inductance of 136 μH.

FIGS. 5B through 5D illustrate FLM inductors 410 formed on a surface of substrate 110. Surface 140 is any surface 140 of substrate 110. Because the FLM inductors 410 of FIGS. 5B through 5D are formed on a single surface 140 of substrate 110, no via 420 is required to couple these exemplary inductors 410 to substrate 110.

FIG. 5B illustrates another example inductor 410 made of fine lines of metal or other conductive material that is formed on the substrate 110 of FIG. 2. As provided by FIG. 5B, the FLM forms a repeating rectangular pattern resembling the prongs of a fork. FIG. 5C illustrates another example inductor 410 made of fine lines of metal or other conductive material that is formed on the substrate 110 of FIG. 2. As provided by FIG. 5C, the FLM forms a spiral pattern similar to the pattern of FIG. 5A. The spiral pattern of FIG. 5C is a double spiral pattern where the FLM forms an inwardly spiraling loop starting from the outside of the spiral and then after reaching the center of the spiral forms outward. FIG. 5D illustrates another example inductor 410 made of fine lines of metal or other conductive material that is formed on the substrate 110 of FIG. 2. As provided by FIG. 5D, the FLM forms a repeating triangular pattern to form inductor 410 on substrate 110.

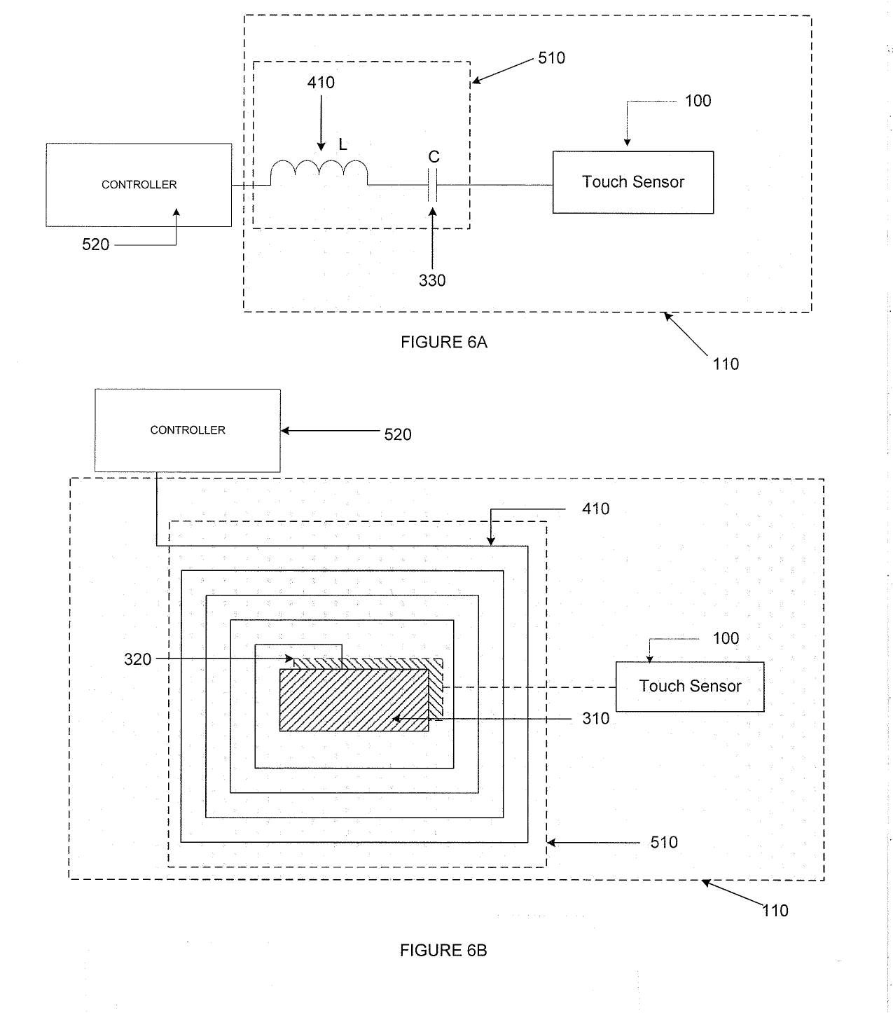

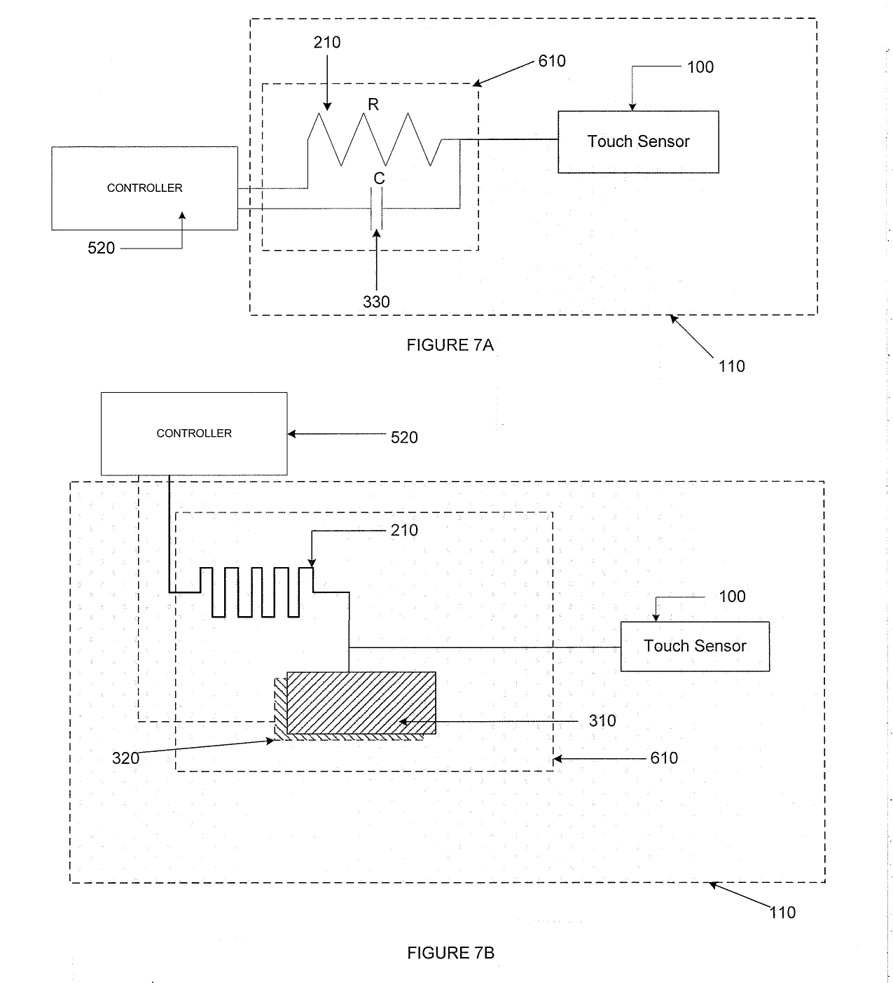

FIGS. 6A, 6B, 7A, and 7B illustrate using electrical components formed using FLM to form electrical circuits on substrate 110. In general, FLM resistors 210, capacitors 330, and inductors 410 are electrically coupled on a surface 140 of substrate 110 to form circuit elements such as filters 510. FIGS. 6A and 6B will illustrate a particular LC filter 510 formed using capacitor 330 and inductor 410. FIGS. 7A and 7B will illustrate a particular RC filter 610 formed using resistor 210 and capacitor 330.

FIG. 6A is a schematic diagram of an example LC filter 510 made of fine lines of metal or other conductive material formed on the substrate 110 of FIG. 2. As provided by FIG. 6A, LC filter 510 includes inductor 410 electrically coupled in series to capacitor 330. LC filter 510 is formed on a surface 140 of substrate 110. In particular embodiments, touch sensor 100 and controller 520 electrically couple to LC filter 510. In this manner, signals from controller 520 are filtered through LC filter 510 before reaching touch sensor 100. The circuit elements are desired with suitable inductance and capacitance values so that, LC filter 510 reduces the strength of signals with certain frequencies. As an example and not by way of limitation, LC filter 510 is designed to filter signals with frequencies above 250 kilohertz and below 100 kilohertz. If controller 520 attempts to send a signal with a 500 kilohertz component to touch sensor 100, LC filter 510 will reduce the strength of that component of the signal. In this manner, LC filter 510 acts as a lock through which only particular controller 520 may operate the touch sensor 100.

FIG. 6B illustrates another example LC filter 510 made of fine lines of metal or other conductive material formed on the substrate 110 of FIG. 2. As provided by FIG. 6B, FLM forms an inwardly spiraling loop to form inductor 410. At the center of the loop, the FLM forms the top plate 310 of capacitor 330 on one surface 140 of the substrate 110. FLM is further used to form the bottom plate 320 of capacitor 330 on another surface 140 of the substrate 110. The bottom plate 320 of capacitor 330 electrically couples to controller 520. The outer spiral of inductor 410 couples to controller 520. In this manner, LC filter 510 is formed, and is electrically coupled between touch sensor 100 and controller 520.

FIG. 7A is a schematic diagram of an example RC filter 610 made of fine lines of metal or other conductive material formed on the substrate 110 of FIG. 2. As provided by FIG. 7A, RC filter 610 includes resistor 210 electrically coupled in parallel to capacitor 330. RC filter 610 is formed on a surface 140 of substrate 110. In particular embodiments, touch sensor 100 and controller 520 electrically couple to RC filter 610. In this manner, signals from controller 520 are filtered through RC filter 610 before reaching ctouch sensor 100. The circuit elements are desired with suitable resistance and capacitance values so that, RC filter 610 reduces the strength of signals with certain frequencies. As an example and not by way of limitation, RC filter 610 is designed to filter signals with frequencies below 100 kilohertz. If controller 520 attempts to send a signal with a 75 kilohertz component to touch sensor 100, RC filter 610 will reduce the strength of that component of the signal. In this manner, RC filter 610 acts as a lock through which only particular controllers 520 may operate the touch sensor 100.

FIG. 7B illustrates another example RC filter 610 made of fine lines of metal or other conductive material formed on the substrate 110 of FIG. 2. As provided by FIG. 7B, FLM forms a repeating rectangular pattern to form resistor 210. FLM further forms the top plate 310 of capacitor 330 on one surface 140 of the substrate 110. The top plate 310 of capacitor 330 and resistor 210 electrically couple to touch sensor 100. FLM is further used to form the bottom plate 320 of capacitor 330 on another surface 140 of the substrate 110. The bottom plate 320 of capacitor 330 and resistor 210 electrically couple to controller 520. In this manner, RC filter 610 is formed, and is electrically coupled between touch sensor 100 and controller 520.

Although this disclosure describes the FLM formed into a particularly shaped pattern to form resistor 210, this disclosure contemplates the FLM formed into any suitable shape and configuration to form resistor 210.

Although this disclosure describes the plates of capacitor 330 being formed in a particular manner, this disclosure contemplates the plates of capacitor 330 being formed in any suitable manner. Although this disclosure describes first plate 310 being in a particular configuration with respect to second plate 320, this disclosure contemplates first plate 310 being in any suitable configuration with respect to second plate 320.

Although this disclosure describes arranging the FLM in a particular manner to form inductor 410, this disclosure contemplates arranging the FLM in any suitable manner to form inductor 410. Although this disclosure describes inductor 410 coupled to particular surfaces 140 of substrate 110 using via 420, this disclosure contemplates inductor 410 coupled to any suitable surfaces 140 of substrate 110 using via 420, such as for example a side surface 140 of substrate 110. Although this disclosure describes FLM forming particular shapes to form inductor 410 on a surface 140 of substrate 110, this disclosure contemplates the FLM forming any suitable shape to form inductor 410 on a surface 140 of substrate 110.

Although this disclosure describes a particular circuit element formed using particular electrical components made with FLM, this disclosure contemplates any suitable circuit element being formed using any suitable combination of electrical components made using FLM. Although this disclosure describes forming passive electrical components (such as for example, a resistor, capacitor, and inductor) using particular materials, this disclosure contemplates forming passive electrical components using any suitable materials (such as for example, the conductive material used to form portions of touch sensor 100 such as electrodes and tracks 140).

Although this disclosure describes inductor 410 and capacitor 330 being of particular shapes and configurations with respect to each other, this disclosure contemplates inductor 410 and capacitor 330 being of any suitable shape and any suitable configuration with respect to each other. Although this disclosure describes resistor 210 and capacitor 330 being of particular shapes and configurations with respect to each other, this disclosure contemplates resistor 210 and capacitor 330 being of any suitable shape and any suitable configuration with respect to each other. Although this disclosure describes filters 510 and 610 filtering signals that include particular frequency components, this disclosure contemplates filters 510 and 610 being a low-pass, high-pass, band-pass, band-stop, or any other suitable type of filter that filters signals that include any suitable frequency components.

Herein, reference to a computer-readable storage medium encompasses one or more non-transitory, tangible computer-readable storage media possessing structure. As an example and not by way of limitation, a computer-readable storage medium may include a semiconductor-based or other integrated circuit (IC) (such, as for example, a field-programmable gate array (FPGA) or an application-specific IC (ASIC)), a hard disk, an HDD, a hybrid hard drive (HHD), an optical disc, an optical disc drive (ODD), a magneto-optical disc, a magneto-optical drive, a floppy disk, a floppy disk drive (FDD), magnetic tape, a holographic storage medium, a solid-state drive (SSD), a RAM-drive, a secure digital card, a secure digital drive, or another suitable computer-readable storage medium or a combination of two or more of these, where appropriate. Herein, reference to a computer-readable storage medium excludes any medium that is not eligible for patent protection under 35 U.S.C. §101. Herein, reference to a computer-readable storage medium excludes transitory forms of signal transmission (such as a propagating electrical or electromagnetic signal per se) to the extent that they are not eligible for patent protection under 35 U.S.C. §101. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

This disclosure encompasses all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative.

What is claimed is:

1. An apparatus comprising:
a substrate;
a touch sensor disposed at least in part on the substrate; and
a passive electrical component formed at least in part of conductive material disposed on a surface of the substrate.

2. The apparatus of claim 1 wherein the passive electrical component is a resistor, capacitor, or inductor.

3. The apparatus of claim 1 wherein the passive electrical component is a capacitor comprising two plates, each plate formed of conductive material.

4. The apparatus of claim 3 wherein the two plates are disposed on opposing surfaces of the substrate.

5. The apparatus of claim 1 further comprising a second passive electrical component formed at least in part of conductive material disposed on the surface of the substrate, the second passive electrical component electrically coupled to the passive electrical component.

6. The apparatus of claim 5 wherein the passive electrical component is an inductor and the second passive electrical component is a capacitor.

7. The apparatus of claim 6, wherein the inductor and the capacitor form a filter that is electrically coupled to the touch sensor.

8. The apparatus of claim 5 wherein the passive electrical component is a resistor and the second passive electrical component is a capacitor.

9. The apparatus of claim 8, wherein the resistor and the capacitor form a filter that is electrically coupled to the touch sensor.

10. The apparatus of claim 7 or 9 further comprising a controller, wherein the filter filters some aspect of the signals passed between the touch sensor and the controller.

11. A method comprising:
providing a substrate;
disposing a touch sensor on the substrate;
forming at least a part of a passive electrical component of conductive material; and
disposing the passive electrical component on a surface of the substrate.

12. The method of claim 11 wherein the passive electrical component is a resistor, capacitor, or inductor.

13. The method of claim 11 wherein the passive electrical component is a capacitor comprising two plates, each plate formed of conductive material, and the two plates disposed on opposing surfaces of the substrate.

14. The method of claim 11 further comprising a second passive electrical component formed at least in part of conductive material disposed on the surface of the substrate, the second passive electrical component electrically coupled to the passive electrical component.

15. The method of claim 14 wherein the passive electrical component is an inductor and the second passive electrical component is a capacitor.

16. The method of claim 15 wherein the inductor and the capacitor form a filter that is electrically coupled to the touch sensor.

17. The method of claim 14 wherein the passive electrical component is a resistor and the second passive electrical component is a capacitor.

18. The method of claim 17 wherein the resistor and the capacitor form a filter that is electrically coupled to the touch sensor.

19. The method of claim 16 or 18 wherein the filter filters some aspect of the signals passed between the touch sensor a controller.

20. A system comprising:
a substrate element;
a sensor element disposed on the substrate element; and
a passive electrical element formed at least in part of conductive material disposed on a surface of the substrate element.

21. The system of claim 20 wherein the passive electrical element is a resistor, capacitor, or inductor.

22. The system of claim 20 wherein the passive electrical element is a capacitor comprising two plates, each plate formed of conductive material, and the two plates disposed on opposing surfaces of the substrate.

23. The system of claim 20 further comprising a second passive electrical element formed at least in part of conductive material disposed on the surface of the substrate, the second passive electrical element electrically coupled to the passive electrical element.

24. The system of claim 23 wherein the passive electrical element is an inductor and the second passive electrical element is a capacitor.

25. The system of claim 24 wherein the inductor and the capacitor form a filter element that is electrically coupled to the sensor element.

26. The system of claim 23 wherein the passive electrical element is a resistor and the second passive electrical element is a capacitor.

27. The system of claim 26 wherein the resistor and the capacitor form a filter element that is electrically coupled to the sensor element.

28. The system of claim 25 or 27 further comprising a controller element, wherein the filter element filters some aspect of the signals passed between the sensor element and the controller element.

29. An apparatus comprising:
a controller;
a touch sensor, portions of which are made of a conductive material; and
a filter electrically coupled to the controller and to the touch sensor, the filter formed at least in part of the conductive material.

30. The apparatus of claim 29 wherein the filter comprises a resistor formed at least in part of the conductive material and a capacitor formed at least in part of the conductive material.

31. The apparatus of claim 29 wherein the filter comprises an inductor formed at least in part of the conductive material and a capacitor formed at least in part of the conductive material.

32. The apparatus of claim 29 wherein the portions of the touch sensor comprise tracks made of the conductive material.

33. The apparatus of claim 29 wherein the portions of the touch sensor comprise electrodes made of the conductive material.
